(19) United States
(12) Patent Application Publication
(10) Pub. No.: US 2003/0019423 A1
(43) Pub. Date: Jan. 30, 2003

(54) Structure and method for fabricating semiconductor structures and devices utilizing the formation of a compliant gallium nitride substrate

(75) Inventors: Jamal Ramdani, Chandler, AZ (US); Lyndee L. Hilt, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/911,702

(22) Filed: Jul. 25, 2001

(51) Int. Cl. C30B 25/00; H01L 29/76; H01L 31/036; C30B 28/12; H01L 21/30; H01L 21/46; C30B 28/14; H01L 31/112; C30B 23/00

(52) U.S. Cl. 117/84

(57) ABSTRACT

High quality epitaxial layers of monocrystalline materials can be grown overlying monocrystalline substrates such as large silicon wafers or compound semiconductor wafers by forming a compliant substrate for growing the monocrystalline layers. In particular, a compliant large area GaN substrate can be fabricated for forming semiconductor structures and devices. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. In addition, formation of a compliant large area GaN substrate may include utilizing surfactant enhanced epitaxy, epitaxial growth of single crystal silicon onto single crystal oxide, and epitaxial growth of Zintl phase materials and the resulting large area GaN substrate may be formed as a defect free stand alone substrate.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of GaN semiconductor material, as well as a method for forming large area GaN substrates including stand alone GaN substrates.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area compound semiconductor substrate or large area thin film of high quality monocrystalline material was available at low cost, a variety of semiconductor devices could advantageously be fabricated in or using that large area substrate or thin film at a low cost compared to the cost of fabricating such devices or large area substrates beginning with a bulk wafer of that compound semiconductor material or in an epitaxial film of such material on a bulk wafer of semiconductor material. In addition, if a large area compound semiconductor substrate or large area thin film of high quality monocrystalline material could be realized beginning with a bulk wafer such as a silicon wafer, an integrated device structure could be achieved that took advantage of the best properties of both the silicon and the high quality monocrystalline material or of the high quality monocrystalline compound semiconductor susbstrate if the device was formed on such a stand alone substrate.

The compound semiconductor gallium nitride (GaN) is of great importance in creating optoelectronic and radio frequency (RF) devices. Accordingly, a need exists for a high quality monocrystalline large area GaN stand alone substrate or large area thin film or layer formed over another monocrystalline material and for a process for making such a stand alone substrate and structure. In other words, there is a need for providing the formation of a high quality monocrystalline large area GaN substrate layer that is compliant with, and can be separated from, an underlying monocrystalline substrate so that quality semiconductor structures, devices and integrated circuits can be formed on the large are GaN monocrystalline layer or large area GaN stand alone substrate. The high quality large area monocrystalline GaN layer or stand alone substrate will have the same crystal orientation as an underlying substrate on which it was formed and will be less expensive to produce than a bulk wafer of GaN semiconductor material.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-13 illustrate schematically, in cross-section, the formation of a device structure in accordance with another embodiment of the invention;

FIGS. 14-18 illustrate schematically, in cross-section, the formation of a device structure in accordance with still another embodiment of the invention; and

FIGS. 19-20 illustrate schematically, in cross-section, the separation of the substrate from a layer forming another substrate Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIB and VB elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

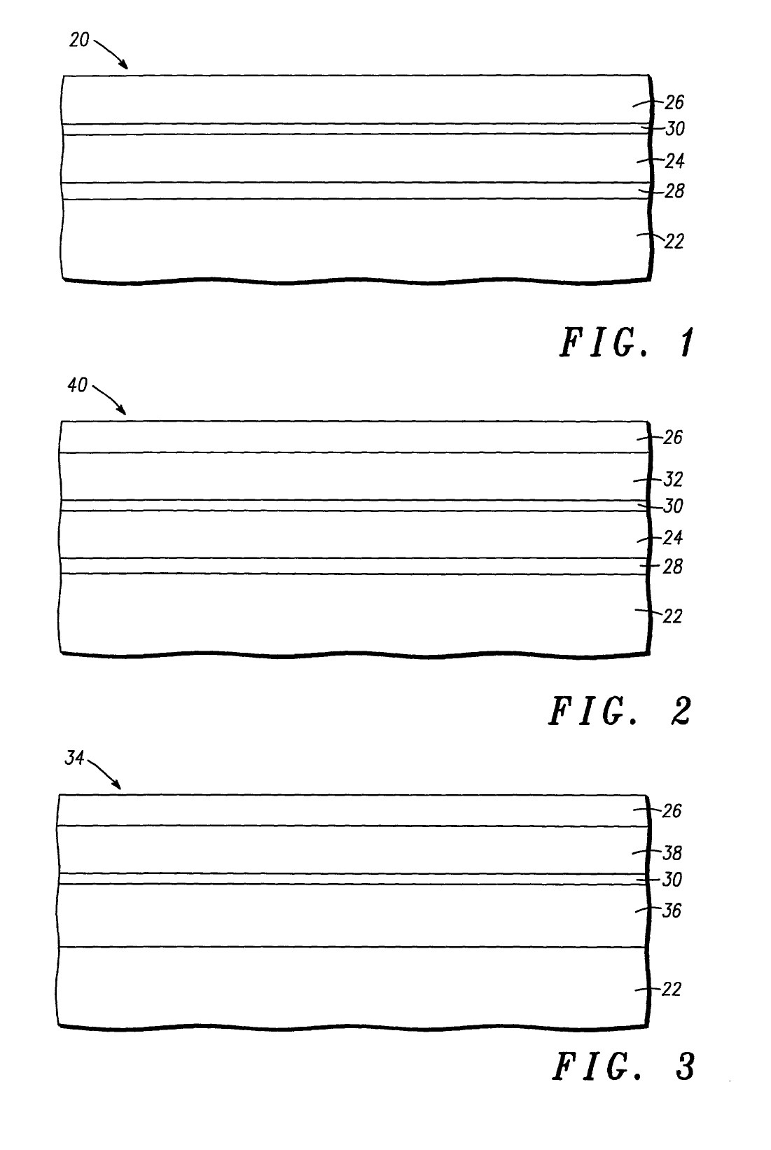

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker μm layers may be fabricated if needed. The amorphous intermediate layer of silicon oxide can have a thickness of about 0.5-5 μm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O.

By way of a preferred example, 1-2 monolayers of Ti—As or Sr—Ga—O have been illustrated to successfully grow GaAs layers.

### EXAMPLE 2

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 μm and preferably has a thickness of about 100-200 μm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 3

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

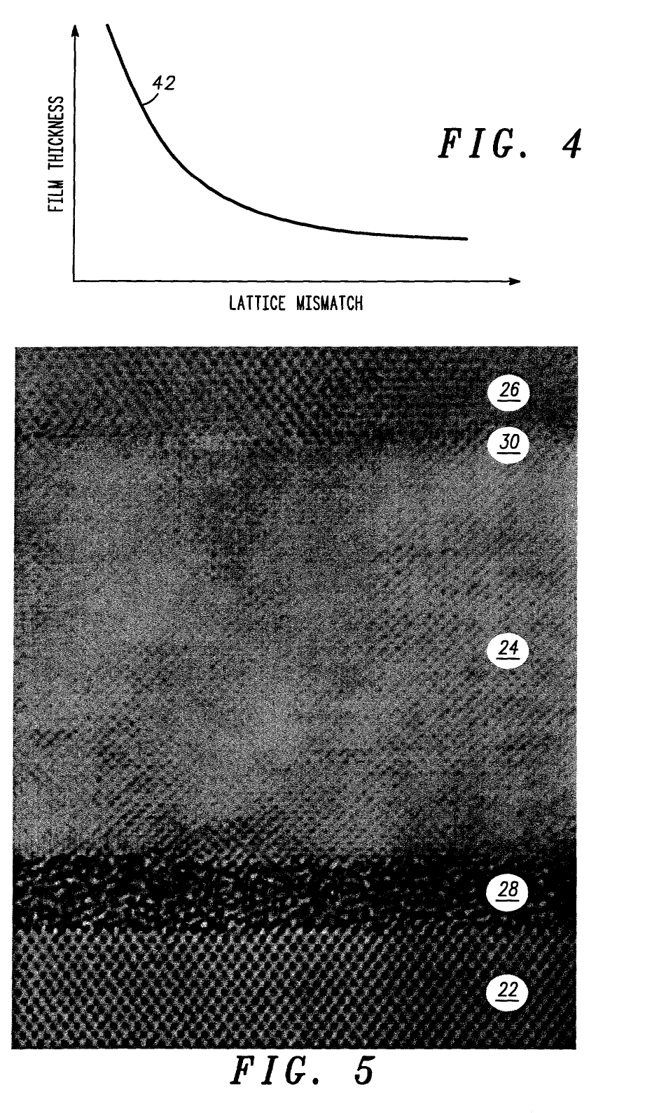

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

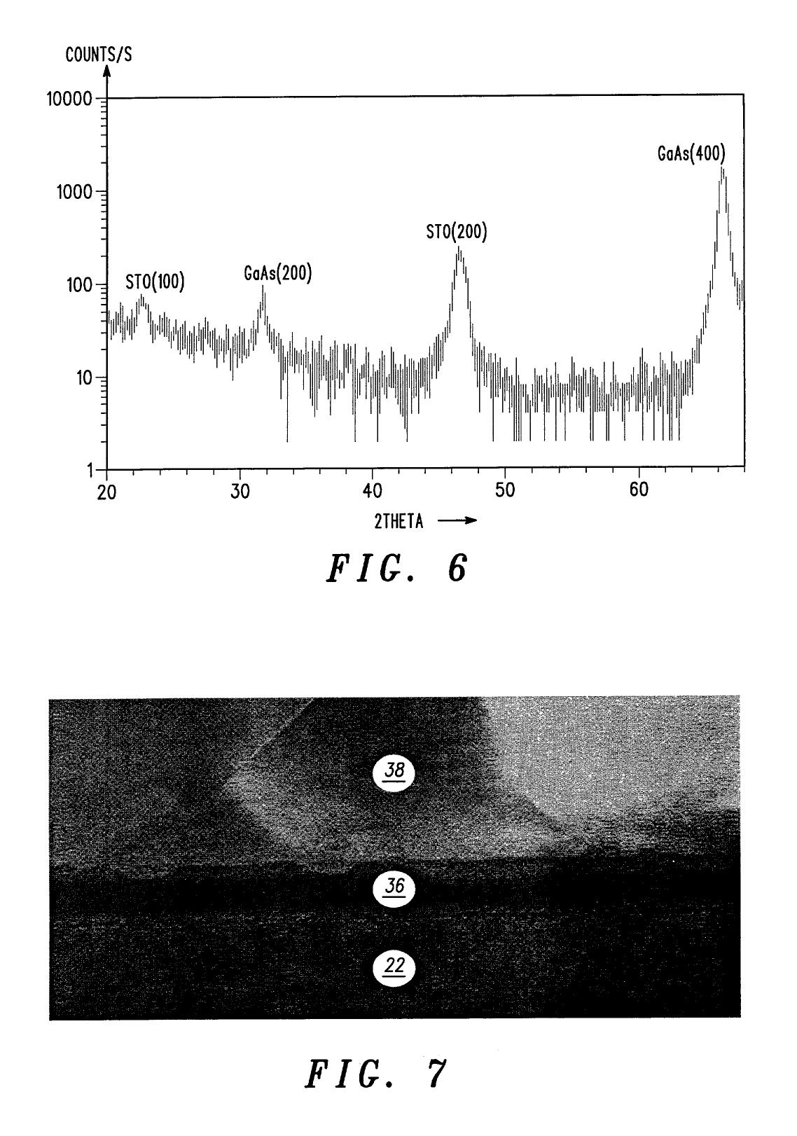

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

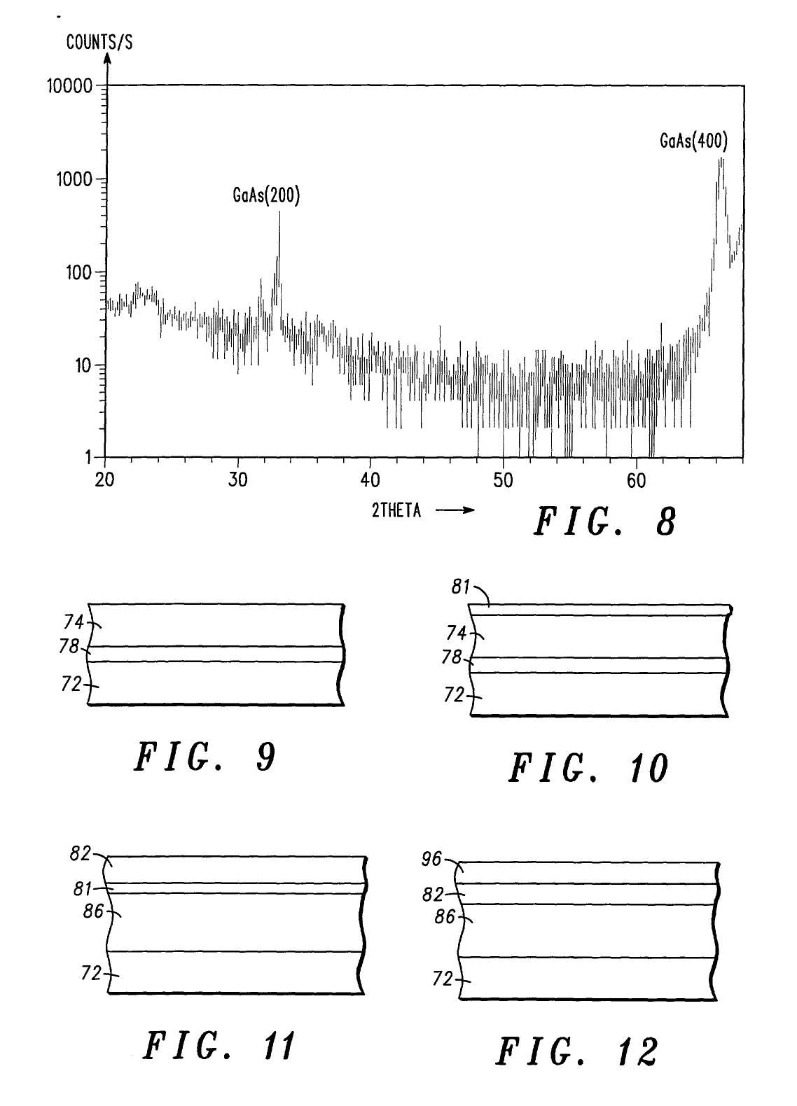

Turning now to FIGS. 9-13, the formation of a device structure in accordance with another exemplary embodiment of the invention is illustrated in cross-section. This embodiment utilizes the formation of a compliant substrate which relies on the epitaxial growth of a single crystal oxide on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 9. Monocrystalline oxide layer 74 may be comprised of any of those materials previously discussed with reference to layer 24 in FIGS. 1 and 2, while amorphous interface layer 78 is preferably comprised of any of those materials previously described with reference to layer 28 illustrated in FIGS. 1 and 2. Substrate 72, although preferably silicon, may also comprise any of those materials previously described with reference to substrate 22 in FIGS. 1-3.

Next, a thin silicon layer 81 is deposited over monocrystalline oxide layer 74 via MBE, CVD, MOCVD, MEE, ALE, PVD, CSD, PLD, and the like as illustrated in FIG. 10 with a thickness of a few hundred Angstroms, but preferably with a thickness of about 50 Angstroms. Monocrystalline oxide layer 74 which underlies silicon layer 81 preferably has a thickness of about 20-100 Angstroms.

Carbonization of silicon layer 81 is then performed by way of rapid thermal annealing conducted in the presence of a carbon source such as acetylene or methane, for example, at a temperature within a range of about 800-1000° C. to form capping layer 82 and silicate amorphous layer 86. However, other suitable carbon sources may be used as long as the rapid thermal annealing step functions to i) amorphize monocrystalline oxide layer 74 and amorphous interface layer 78 into a silicate amorphous layer 86, and ii) carbonize top silicon layer 81 to form capping layer 82 which in this example would be a silicon carbide (SiC) layer as illustrated in FIG. 11. The formation of amorphous layer 86 is similar to the formation of layer 36 illustrated in FIG. 3 and may comprise any of those materials described with reference to layer 36 in FIG. 3. However, the preferable material for layer 36 will be dependent upon the material of capping layer 82 used for silicon layer 81. Finally, as shown in FIG. 12, a compound semiconductor layer 96, such as gallium nitride (GaN) is grown over the SiC surface by way of MBE, CVD, MOCVD, MEE, ALE, PVD, CSD, PLD, or the like to form a high quality GaN compound semicondcutor material for device formation.

Alternatively, the anneal process may be carried out subsequent to growth of layer 96. For example, vapor phase epitaxy may be used to grow a 100 to 500 micrometer thick GaN layer at a rate of about 10 to 20 micrometers per hour. The growth of the GaN layer 96 is carried out at a high temperature, e.g. 800° C., which leads to the amorphization of the monocrystalline oxide layer 74. The deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Finally, monocrystalline compound semiconductor GaN layer 96 is separated from substrate layer 72 by the removal of silicate from the structure using standard etching techniques such as hydrogen fluoride (HF) or buffered HF to obtain a stand alone defect free large area GaN substrate layer 96 as shown in FIG. 14. A broad variety of semiconductor structures and devices may be formed within and/or on the resulting GaN substrate.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moroever, unlike past use of a SiC substrate, this embodiment of the invention is not limited by wafer size which is usually less than 50 mm in diameter for prior art SiC substrates. Also, this method allows for the creation of a large area stand alone GaN substrate at a much lower cost than utilizing a bulk wafer of GaN.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 14-18 schematically illustrate, in cross-section, the formation of another embodiment of a structure in accordance with the present invention. Like the previous embodiment described with reference to FIGS. 9-13, this embodiment utilizes the formation of a compliant substrate which relies on the epitaxial growth of a single crystal oxide on a substrate. However, in this embodiment, a single crystal oxide is epitaxially grown on a GaAs substrate followed by the epitaxial growth of monocrystalline GaAs onto the oxide.

Like the embodiments described with reference to FIG. 9, an accommodating buffer layer 104 is grown on a substrate layer 102 with an amorphous interface layer 108 as illustrated in FIG. 14. Like accommodating buffer layer 74 described with reference to FIG. 9, accommodating buffer layer 104 is a monocrystalline oxide layer preferably comprised of those materials previously discussed with reference to FIGS. 1 and 2. Further, like amorphous interface layer 78 shown in FIG. 9, amorphous interface layer 108 is comprised of any of those materials previously described with reference to layer 28 in FIGS. 1 and 2. Finally, like layer 22 in FIGS. 1-3 and layer 72 in FIG. 9, substrate 102 may comprise any of those materials previously described with reference to FIGS. 1-3 but in this particular embodiment comprises GaAs.

In accordance with this embodiment of the invention, the epitaxial growth of a GaAs thin film 112 on top of accommodating buffer layer 104 is facilitated by a template layer 110 which is formed by capping layer 104 as shown in FIGS. 15-16. Template layer 110 is preferably 1-10 monolayers of Ti—As, Sr—O—As, Sr—Ga—O, or Sr—Al—O. By way of a preferred example, 1-2 monolayers of Ti—As or Sr—Ga—O have successfully grown GaAs layers. GaAs thin film 112 preferably comprises a thickness of about 50 Angstroms.

Next, the nitridation of GaAs thin film 112 is carried out by way of exposure to nitrogen plasma to form a GaN surface layer 106 as shown in FIG. 17. A thick GaN layer 106, preferably having a thickness of approximately 0.1 to 1.0 microns, is grown on GaN surface layer 106 by way of MBE, CVD, MOCVD, MEE, ALE, PVD, CSD, PLD or the like to form high quality GaN for device formation on or within the GaN layer. As previously described with reference to the embodiment shown in FIGS. 9-13, vapor phase epitaxy may be used to grow GaN layer 106 into a thicker layer of GaN at a rate of about 10-20 micrometers per hour to a thickness of about 100-500 micrometers. The growth of GaN layer 106 is carried out at high temperature, e.g. 800° C., which causes the amorphization of layers 104 and 108 to form amorphous layer 116.

As previously stated, the deposition of GaN and GaN based systems will result in the formation of dislocation nets confined at the silicon/amorphous region and the resulting nitride containing compound semiconductor material, i.e. the GaN or GaN based system, is defect free.

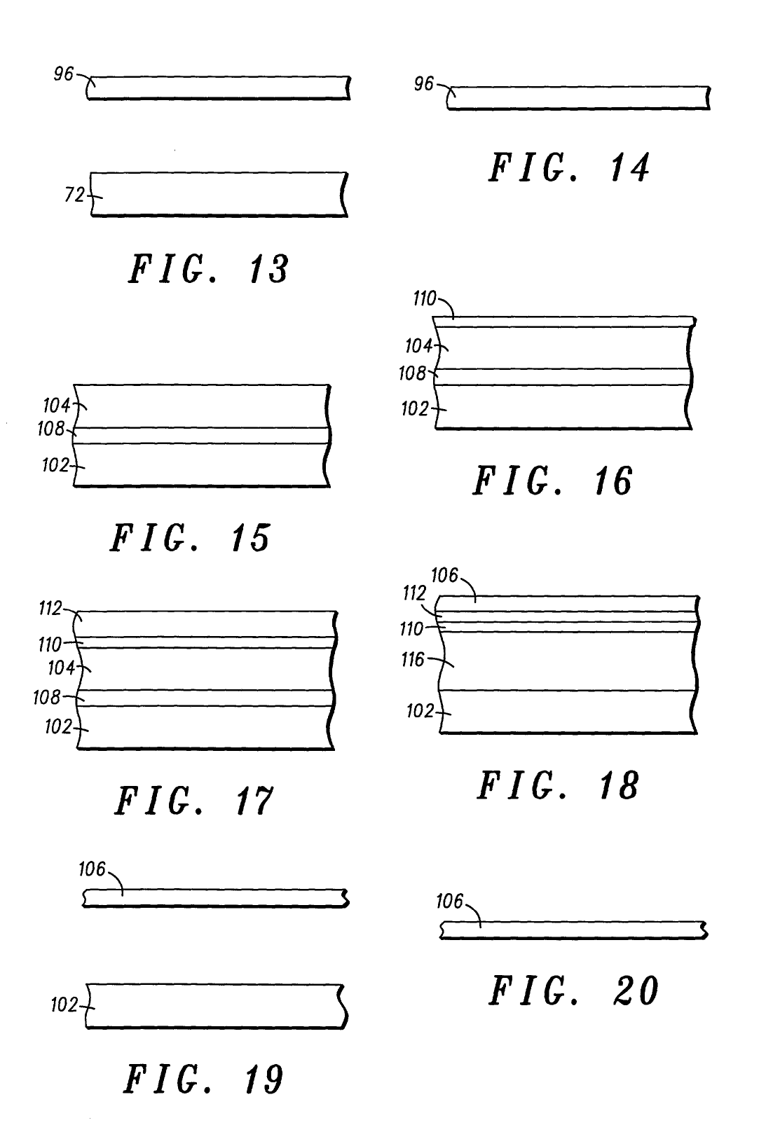

The monocrystalline compound semiconductor GaN layer 106 is then separated from substrate layer 102 using standard etching techniques to form a stand alone defect free large area GaN substrate layer 106 as shown in FIGS. 19 and 20.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters. Furthermore, particular embodiments described herein, particularly with reference to FIGS. 9-18, allow for the formation of a stand alone defect free large area GaN substrate layer upon and within which numerous devices may be formed.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A process for fabricating a large area monocrystalline compound semiconductor nitride containing substrate comprising the steps of:
providing a monocrystalline silicon substrate;
epitaxially growing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor nitride containing layer overlying the monocrystalline perovskite oxide film;
thermally annealing the oxide film to form a second amorphous layer; and
separating the epitaxially formed monocrystalline compound semiconductor nitride containing layer from the substrate, the second amorphous layer, and the interface layer to form a stand alone nitride containing substrate.

2. The process of claim 1 wherein the step of thermally annealing comprises the step of rapid thermal annealing.

3. The process of claim 2 wherein the step of rapid thermal annealing comprises rapid thermal annealing at a temperature between about 700° C. and about 1000° C.

4. The process of claim 1 further comprising the step of forming a first template layer on the monocrystalline semiconductor substrate.

5. The process of claim 4 wherein the step of providing a monocrystalline semiconductor substrate comprises providing a substrate comprising silicon having a silicon oxide layer on a surface thereof and the step of forming a first template layer comprises the steps of:
depositing a material from the group consisting of alkali earth metals and alkali earth metal oxides onto the silicon oxide layer; and
heating the substrate to react the material with the silicon oxide.

6. The process of claim 5 wherein the alkali earth metals comprise an alkali earth metal from the group consisting of barium, strontium, and mixtures of barium and strontium, and the earth metal oxides comprise an alkali earth metal oxide from the group consisting of barium oxide, strontium oxide, and barium strontium oxide.

7. The process of claim 1 wherein the step of epitaxially growing a monocrystalline perovskite oxide film comprises the steps of:
heating the monocrystalline semiconductor substrate to a temperature between about 200° C. and about 800° C.; and
introducing reactants comprising strontium, titanium, and oxygen.

8. The process of claim 7 wherein the step of introducing comprises controlling the ratio of strontium to titanium and controlling partial pressure of oxygen.

9. The process of claim 8 wherein the step of oxidizing the monocrystalline semiconductor substrate comprises increasing the partial pressure of oxygen above a level necessary for epitaxially growing the monocrystalline oxide layer.

10. The process of claim 1 further comprising the step of forming a second template layer overlying the monocrystalline oxide layer.

11. The process of claim 10 wherein the step of forming a second template layer comprises the step of capping the monocrystalline oxide layer with a layer comprising a monolayer of material selected from the group consisting of titanium, titanium and oxygen, strontium, and strontium and oxygen.

12. The process of claim 11 wherein the step of epitaxially forming a monocrystalline nitride containing compound semiconductor layer comprises:
depositing a nitride material on the second template layer; and
reacting the nitride material with the material of the second template layer.

13. The process of claim 12 wherein the step of epitaxially forming a monocrystalline nitride containing compound semiconductor layer further comprises the steps of depositing a Group III material and a nitride material to form a III-V nitride containing compound semiconductor material after the step of reacting.

14. The process of claim 13 wherein the step of thermal annealing comprises the step of rapid thermal annealing the monocrystalline oxide film after the step of epitaxially forming a monocrystalline nitride containing compound semiconductor layer.

15. The process of claim 13 wherein the step of thermal annealing comprises the step of thermal annealing the monocrystalline oxide film in the presence of an over pressure of the nitride material.

16. The process of claim 13 wherein the step of thermal annealing comprises heating the monocrystalline oxide film at a temperature selected so as not to degrade the III-V nitride containing compound semiconductor material.

17. The process of claim 1 wherein the step of epitaxially forming a monocrystalline nitride containing compound semiconductor layer comprises the steps of:
depositing a thin silicon film over the monocrystalline oxide film; and
carbonizing the thin silicon film to form a silicon carbide capping layer.

18. The process of claim 17 further comprising the step of growing a nitride containing compound semiconductor layer over the silicon carbide capping layer.

19. The process of claim 18 wherein the step of growing a nitride containing compound semiconductor layer comprises the step of growing a GaN layer over the silicon carbide capping layer.

20. The process of claim 19 wherein the step of thermal annealing comprises the step of thermal annealing the monocrystalline oxide film in the presence of an over pressure of carbon.

21. The process of claim 19 wherein the step of thermal annealing comprises the step of rapid thermal annealing the monocrystalline oxide film after the step of epitaxially forming a monocrystalline nitride containing compound semiconductor layer.

22. The process of claim 21 wherein the step of thermal annealing comprises heating the monocrystalline oxide film at a temperature selected so as not to degrade the GaN compound semiconductor layer.

23. The process of claim 1 wherein the step of epitaxially forming a monocrystalline nitride containing compound semiconductor layer comprises the steps of:
depositing a thin template layer over the monocrystalline oxide film;
forming a thin GaAs layer over the thin template layer; and
nitridating the GaAs layer to form a GaN surface.

24. The process of claim 23 further comprising the step of epitaxially growing a thick GaN layer on the GaN surface.

25. The process of claim 24 wherein the step of thermal annealing comprises the step of thermal annealing the monocrystalline oxide film in the presence of an over pressure of nitrogen.

26. The process of claim 24 wherein the step of thermal annealing comprises the step of rapid thermal annealing the monocrystalline oxide film after the step of epitaxially forming a monocrystalline GaN layer.

27. The process of claim 21 wherein the step of thermal annealing comprises heating the monocrystalline oxide film at a temperature selected so as not to degrade the GaN compound semiconductor layer.

28. A process for forming a semiconductor structure comprising the steps of:
providing a monocrystalline oxide layer having a surface;
forming a template layer on the surface;
epitaxially growing a monocrystalline compound semiconductor layer overlying the template;
thermally annealing the monocrystalline oxide layer to convert the monocrystalline oxide layer to an amorphous oxide layer; and
separating the monocrystalline compound semiconductor layer from the rest of the semiconductor structure.

29. The process of claim 28 wherein the step of providing a monocrystalline oxide layer comprises epitaxially growing a monocrystalline oxide layer lattice matched to an underlying monocrystalline silicon substrate.

30. The process of claim 29 wherein the step of epitaxially growing a monocrystalline oxide layer comprises growing a monocrystalline oxide layer having a thickness of about 2-10 nm.

31. The process of claim 30 wherein the step of thermally annealing comprises rapid thermal annealing.

32. The process of claim 30 wherein the step of thermally annealing comprises thermal annealing at a temperature between about 700 and 1000° C.

33. The process of claim 28 wherein the step of providing a monocrystalline oxide layer comprises providing an oxide layer comprising SrₓBa₁₋ₓTiO₃ where x ranges from 0 to 1.

34. The process of claim 28 wherein the step of forming a template layer comprises capping the monocrystalline oxide layer with 1 to 10 monolayers of a material selected from Ti—As and Sr—Ga—O.

35. The process of claim 34 wherein the step of epitaxially growing a monocrystalline compound semiconductor layer comprises growing a nitride containing layer.

36. The process of claim 35 wherein said step of epitaxially growing a monocrystalline compound semiconductor layer comprises the steps of:
depositing a thin GaAs film on the template layer; and
nitridating the GaAs film to form a GaN surface.

37. The process of claim 36 further comprising the step of epitaxially growing a GaN layer having a thickness of about 100-500 micrometers on the GaN surface.

38. The process of claim 28 wherein the step of forming a template layer comprises capping the monocrystalline oxide layer with 1 to 10 monolayers of silicon.

39. The process of claim 38 wherein the step of epitaxially growing a monocrystalline compound semiconductor layer comprises growing a nitride containing layer.

40. The process of claim 39 wherein said step of epitaxially growing a monocrystalline compound semiconductor layer comprises the steps of:
carbonizing the silicon layer to form a silicon carbide capping layer; and
epitaxially growing a GaN layer over the silicon carbide capping layer to a thickness of about 100-500 micrometers.

41. A process for fabricating a semiconductor structure comprising the steps of:
providing a monocrystalline semiconductor substrate;
forming an accommodating buffer layer overlying the monocrystalline semiconductor substrate;
forming an amorphous intermediate layer between the monocrystalline semiconductor substrate and the accommodating buffer layer;
epitaxially growing a monocrystalline compound semiconductor layer overlying the accommodating buffer layer; and
separating the monocrystalline compound semiconductor layer from the rest of the structure.

42. The process of claim 41 wherein the step of forming an amorphous intermediate layer comprises the step of diffusing oxygen through the accommodating buffer layer to oxidize the monocrystalline semiconductor substrate.

43. The process of claim 41 wherein the step of forming an accommodating buffer layer comprises the steps of:
growing an epitaxial buffer layer by a process selected from MBE, MOCVD, MEE and ALE; and
after the step of epitaxially growing a monocrystalline compound semiconductor layer, thermally annealing the epitaxial buffer layer to convert the epitaxial layer to an amorphous layer.

44. The process of claim 41 wherein the step of providing a monocrystalline semiconductor substrate comprises providing a monocrystalline silicon substrate having a silicon oxide layer on a surface thereof.

45. The process of claim 44 wherein the step of forming an accommodating buffer layer comprises the steps of:
reacting a material selected from SrₘBa₁₋ₘ where m ranges from 0 to 1 and SrₙBa₁₋ₙO where n ranges from 0 to 1 with the silicon oxide layer to form a template on the silicon substrate surface;
epitaxially depositing a monocrystalline layer comprising SrₓBa₁₋ₓTiO₃ where x ranges from 0 to 1 on the template; and
after the step of epitaxially growing a monocrystalline compound semiconductor layer, thermally annealing the monocrystalline layer comprising SrₓBa₁₋ₓTiO₃ to convert the layer to an amorphous layer.

46. A product formed by the process of claim 1.

47. The product of claim 46 wherein the monocrystalline compound semiconductor nitride containing layer comprises GaN.

48. The product of claim 47 wherein the GaN monocrystalline compound semiconductor layer is formed by depositing a thin silicon film over the monocrystalline oxide film, carbonizing the thin silicon film to form a silicon carbide capping layer, and growing a GaN layer over the silicon carbide capping layer.

49. The product of claim 47 wherein the GaN monocrystalline compound semiconductor layer is formed by depositing a thin template layer over the monocrystalline oxide film, forming a thin GaAs layer over the template layer, nitridating the GaAs layer to form a GaN surface, and growing a thick GaN layer on the GaN surface.

50. The product of claim 49 wherein the thin template layer comprises Ti-As.

51. A product formed by the process of claim 28.

52. The product of claim 51 wherein the monocrystalline oxide layer comprises an epitaxially grown monocrystalline oxide layer that is lattice matched to an underlying monocrystalline silicon substrate.

53. The product of claim 52 wherein the monocrystalline oxide layer comprises SrₓBa₁₋ₓTiO₃ where x ranges from 0 to 1.

54. The product of claim 53 wherein the monocrystalline compound semiconductor layer comprises GaN.

55. The product of claim 54 wherein the GaN layer is formed by depositing a thin GaAs film on the template layer, nitridating the GaAs film to form a GaN surface, and growing a GaN layer on the GaN surface.

56. The product of claim 55 wherein the template layer comprises 1 to 10 monolayers of Ti—As.

57. The product of claim 54 wherein the GaN layer comprises a thickness of about 100-500 micrometers.

58. The product of claim 54 wherein the GaN layer is formed by using a template layer comprising silicon, carbonizing the silicon layer to form a silicon carbide capping layer, and epitaxially growing a GaN layer over the silicon carbide capping layer.

59. The product of claim 58 wherein the template layer comprises 1 to 10 monolayers of silicon.

60. The product of claim 58 wherein the GaN layer comprises a thickness of about 100 to 500 micrometers.

61. A product formed by the process of claim 41.

62. The product of claim 61 wherein the accommodating buffer layer is formed by reacting a material selected from SrₘBa₁₋ₘ where m ranges from 0 to 1 and SrₙBaₙ₋₁O where n ranges from 0 to 1 with the silicon oxide layer to form a template on the silicon substrate surface;
epitaxially depositing a monocrystalline layer comprising SrₓBa₁₋ₓTiO₃ where x ranges from 0 to 1 on the template; and
after the step of epitaxially growing a monocrystalline compound semiconductor layer, thermally annealing the monocrystalline layer comprising SrₓBa₁₋ₓTiO₃ to convert the layer to an amorphous layer.

63. The product of claim 62 wherein the monocrystalline compound semiconductor layer comprises GaN.

64. The product of claim 63 wherein the GaN monocrystalline compound semiconductor layer is formed by depositing a thin silicon film over the monocrystalline oxide film, carbonizing the thin silicon film to form a silicon carbide capping layer, and growing a GaN layer over the silicon carbide capping layer.

65. The product of claim 63 wherein the GaN monocrystalline compound semiconductor layer is formed by depositing a thin template layer over the monocrystalline oxide film, forming a thin GaAs layer over the template layer, nitridating the GaAs layer to form a GaN surface, and growing a thick GaN layer on the GaN surface.

66. The product of claim 65 wherein the thin template layer comprises Ti—As.

67. The product of claim 63 wherein the GaN layer comprises a thickness of about 100 to 500 micrometers.
